(19) United States
(12) Patent Application Publication
(10) Pub. No.: US 2026/0242555 A1
(43) Pub. Date: Aug. 20, 2026

(54) POLYIMIDE FILM, AND PREPARATION METHOD AND USE THEREOF

(71) Applicants: PetroChina Shanghai Advanced Materials Research Institute Co., Ltd., Shanghai (CN); PetroChina Company Limited, Beijing (CN)

(72) Inventors: Jiming YANG, Shanghai (CN); Ruoyuan TAO, Shanghai (CN); Zeqiu LI, Shanghai (CN); Chao SU, Shanghai (CN); Jiacong GUO, Shanghai (CN); Hui ZHOU, Shanghai (CN)

(21) Appl. No.: 19/640,110

(22) Filed: Apr. 6, 2026

Related U.S. Application Data
(63) Continuation of application No. PCT/CN2024/143413, filed on Dec. 27, 2024.

(30) Foreign Application Priority Data
Nov. 1, 2024 (CN) 202411548016.6

(51) Int. Cl. C08J 7/04; B29C 71/02; C08G 73/10; C08J 7/048

(52) U.S. Cl. CPC C08J 7/0423; C08G 73/1021; C08G 73/1028; C08J 7/048; C08J 7/08; C08J 2379/08; C08J 2479/08

(57) ABSTRACT

A polyimide film, and a preparation method and a use thereof, where the polyimide film has a thickness of greater than or equal to 250 μm, and includes a film layer A and at least one-layer film layer B in contact with each other; a surface roughness Rz of the film layer A is less than or equal to 1.0 μm; the number of micropores with a size greater than 0.1 mm in the film layer B is less than or equal to 1/m²; the film layer B has a density of greater than or equal to 1.45 g/cm³, and a surface roughness Rz of greater than or equal to 1.2 μm. The polyimide film provided in the present application has the characteristics of large thickness, small linear thermal expansion coefficient, high pressure resistance and low gas permeability.

### CROSS-REFERENCE TO RELATED APPLICATIONS

This application is a continuation of International Application No. PCT/CN2024/143413, filed on Dec. 27, 2024, which claims priority to Chinese Patent Application No. 202411548016.6 filed with the China National Intellectual Property Administration on Nov. 1, 2024. Both of the aforementioned applications are hereby incorporated by reference in their entireties.

### TECHNICAL FIELD

The present application relates to a polyimide film, and in particular to a polyimide film, and a preparation method and use thereof, and belongs to the technical field of polyimide film manufacturing.

### BACKGROUND

Ultra-thick polyimide films with a thickness greater than 100 μm have excellent heat resistance and thermal insulation properties, outstanding mechanical properties and insulation properties, good chemical stability, and superior dielectric properties. They have been widely used as precursor films for high thermal-conductivity artificial graphite film; substrate films, cover films, and reinforcing films for microelectronic circuit; high-temperature protective films for flexible copper clad laminate processing, protective films for thermal insulation system of lithium-ion battery; protective films for water cooling system of new energy vehicle; insulation films for motor and special electrical appliance, etc. Especially in recent years, with the transformation of 3C electronic products towards compact structure and efficient operation and the development of new energy vehicles towards higher safety and reliability, the market demand for ultra-thick polyimide films with a thickness greater than 100 μm continues to grow.

Polyimide is a “stubborn” polymer material that is difficult to dissolve and melt. Currently, the industrialized polyimide film manufacturing technology mainly adopts a two-step method. Firstly, a polyamic acid solution is prepared by polycondensation of aromatic dianhydride and aromatic diamine in a solvent. Then, a gel film containing a certain amount of solvent is prepared by casting the polyamic acid solution, or a gel film containing a certain amount of solvent is prepared by mixing and casting the polyamic acid with a dehydrating agent, a catalyst, etc. Subsequently, the gel film is subjected to stretching and high-temperature treatment to obtain the polyimide film. With this manufacturing technology, as the thickness of the produced polyimide film increases, the solvent content of the gel film also increases exponentially. The control and effective removal of the solvent content in the gel film during the manufacturing process not only affect the performance of the final polyimide film but also are directly related to the stability and safety of the manufacturing process.

At present, the preparation methods of polyimide films have the following technical difficulties.

1. The difficulty in controlling the uniformity of solvent volatilization in the thickness direction of the gel film increases. The solvent on the surface layer of the gel film is easy to volatilize to form a hard cured layer, while the evaporation of the solvent in the inner layer is hindered, resulting in a “surface drying” phenomenon. The solvent cannot volatilize in time, leading to poor mechanical properties and insufficient self-supporting ability of the gel film. It is easy to tear under tension, causing production interruption or even failure in production.

2. The gel film containing a large amount of solvent is dried while being adhered to a smooth annular steel belt. Due to the rapid and massive volatilization of the solvent, the gel film is prone to severe shrinkage, resulting in narrowed width that fails to meet the processing width for manufacturing process. Moreover, when the gel film runs to the bottom of the annular steel belt, due to the weight of the gel film is too heavy, it will detach from the steel belt if the adhesive bond between the gel film and the steel belt is insufficient, causing the failure to produce the gel film.

3. When the gel film enters the stretching process, a higher processing temperature will cause more severe shrinkage of the gel film, and the gel film is prone to detach from the fixtures; the insufficient mechanical properties of the gel film will also cause it to tear away and detach from the fixtures; the gel film detached from the fixtures accumulates in rolls, and the failure to volatilize a large amount of solvent in time will cause a safety hazard of fire.

4. In addition to the above engineering problems, the excessively fast evaporation of internal solvent during the drying process of the gel film will also lead to an increase in pore defects and insufficient mechanical properties of the prepared ultra-thick polyimide film, resulting in quality issues. Eventually, the produced ultra-thick polyimide film has limited application or even cannot be applied.

Therefore, the balance between the solvent content control and mechanical properties of the intermediate gel film in the production of ultra-thick polyimide films is a key bottleneck.

U.S. Invention Patent application US20220152912A1 discloses a method for manufacturing a polyimide film with a thickness greater than 400 μm. It avoids the above technical difficulties by controlling the thickness and solvent content of a single-layer gel film in combination with a lamination composite method. However, the equipment required for this method is relatively complex, the processing cost is high, and the produced ultra-thick polyimide film can be expected to have obvious interlayer interfaces, which are prone to delamination under high temperature and stress. U.S. Invention Patent application US20220152912A1 also mentions polyimide films with a thickness greater than 200 μm, and its production generally requires drying to remove solvents at a wind speed less than 1 m/min, resulting in extremely low production efficiency, high production cost, and inability to produce polyimide films with a thickness greater than 400 μm. Chinese Invention Patent CN109647683 discloses a method for preparing a polyimide film with a thickness of 50 μm to 135 μm by single or multiple spraying, which can effectively avoid the “surface drying” problem. However, the process used is relatively complex, and the mechanical properties and thermal properties of the produced polyimide film are difficult to meet the application requirements of high-tech industry. Chinese Invention Patent CN108527745A discloses a specially designed drying device, which enables the solvent of gel film to uniformly diffuse and volatilize from one side to the other by heating one side and cooling the other side of the gel film; however, this method is likely to cause the solvent to condense on the surface of the cooling cavity and drip back onto the surface of the gel film, forming striation defects. Chinese Patent CN217654241U discloses an anti-condensation temperature-controlled fire suppression system for polyimide film production, which can effectively solve the problems of gel film detaching from fixtures and fire due to gel film aggregation during high-temperature stretching, but does not involve solutions for regulating the solvent content of thick gel films and balancing their mechanical properties. Chinese Invention Patents CN110423467B, CN101168598A and CN113788478A all mention a method for manufacturing ultra-thick polyimide film, but do not clarify specific solutions to the above technical difficulties. The ultra-thick polyimide films mentioned in the above patents all have a thickness of less than 250 μm, and the manufacturing technology for polyimide films with a thickness greater than 250 μm still needs to be developed.

Therefore, developing a preparation method for polyimide films with a thickness greater than 250 μm has become a key research direction in this field.

### SUMMARY

The present application provides a polyimide film, which has the characteristics of large thickness, small linear thermal expansion coefficient, high pressure resistance and low gas permeability.

The present application also provides a preparation method of a polyimide film, which has the characteristics of being capable of manufacturing a composite polyimide film with two or more layers and reducing the number of pore defects inside the polyimide film.

The present application also provides a circuit board, which has the characteristic of high dimensional stability.

The present application also provides a gas barrier composite film, which has the characteristic of high gas barrier property.

The present application also provides an insulating composite film, which has the characteristic of high insulation property.

The present application provides a polyimide film, where the polyimide film has a thickness of greater than or equal to 250 μm and includes a film layer A and at least one film layer B that are in contact with each other;
a surface roughness Rz of the film layer A is less than or equal to 1.0 μm;
a micropore with a size greater than 0.1 mm in the film layer B is less than or equal to 1 per square meter in number, a density of the film layer B is greater than or equal to 1.45 g/cm³, and a surface roughness Rz of the film layer B is greater than or equal to 1.2 μm.

For the polyimide film as described above, the polyimide film has a linear thermal expansion coefficient of 12 ppm/° C. to 35 ppm/° C., a breakdown voltage of greater than or equal to 30 kV, and a permeability to H₂ of less than or equal to 1.0×10⁻¹⁵ mol·m/m²·s·Pa; and the polyimide in the film layer A has a glass transition temperature of 180° C. to 300° C.

For the polyimide film as described above, a thickness of the film layer A accounts for 20% to 50% of a total thickness of the polyimide film.

The present application also provides a preparation method of a polyimide film, by which any one of the foregoing polyimide films can be prepared. The method includes the following steps:
1) mixing a first aromatic dianhydride, a first aromatic diamine, a low-boiling solvent, a high-boiling solvent, and a filler, and allowing the first aromatic dianhydride and the first aromatic diamine to undergo a polycondensation reaction to obtain a first resin solution;
2) mixing a second aromatic dianhydride, a second aromatic diamine, a high-boiling solvent, and a filler, and allowing the second aromatic dianhydride and the second aromatic diamine to undergo a polycondensation reaction to obtain a second resin solution;
3) performing a first heating and drying treatment on a solution film formed by casting the first resin solution to obtain an initial film layer A;
4) mixing the second resin solution with a chemical imidization reagent and a molecular weight reinforcing agent to obtain a second resin mixed solution; performing at least one stack heating treatment on the initial film layer A using the second resin mixed solution to obtain an initial composite gel film;
5) sequentially performing at least one heating and drying treatment on the initial composite gel film to obtain an intermediate composite gel film;
6) performing a high-temperature heating and biaxial stretching treatment on the intermediate composite gel film to obtain the polyimide film;
where, the first heating and drying treatment has a treatment temperature of 50° C. to 120° C., and a treatment time of 2 min to 10 min;
the stack heating treatment includes attaching the second resin mixed solution to one-side surface of the initial film layer A, and performing a heating treatment at a temperature of 60° C.-150° C. for a time of 5 min-15 min;
the heating and drying treatment for the initial composite gel film has a treatment temperature of 50° C.-180° C., and a treatment time of 18 min-60 min;
the first aromatic dianhydride is selected from at least one of pyromellitic dianhydride, 3,3′,4,4′-biphenyltetracarboxylic dianhydride, 2,3,3′,4-biphenyltetracarboxylic dianhydride, 4,4′-oxydiphthalic dianhydride, 3,4,3′,4′-triphenyl diether dianhydride, 2,2-bis[4-(3,4-dicarboxyphenoxy)phenyl]propane dianhydride, 2,2-diphenylpropane-3,4,3′,4′-tetracarboxylic dianhydride, 3,3′,4,4′-benzophenonetetracarboxylic dianhydride, 3,3′,4,4′-diphenyl sulfone tetracarboxylic dianhydride, and p-phenylene-bis-trimellitate dianhydride;
the first aromatic diamine is selected from at least one of 4,4′-diaminodiphenyl ether, 2,2-bis[4-(4-aminophenoxy)phenyl]propane, 4,4′-diaminodiphenylmethane, 2,2-bis(4-aminophenyl)propane, 1,3-bis(3-aminophenoxy)benzene, 1,4-bis(4-aminophenoxy)benzene, 2,4-diaminotoluene, and 1,3-bis(aminopropyl)tetramethyldisiloxane;
the second aromatic dianhydride is selected from at least one of pyromellitic dianhydride and 3,3′,4,4′-biphenyltetracarboxylic dianhydride;
the second aromatic diamine is selected from at least one of 4,4′-diaminodiphenyl ether and 1,4-phenylenediamine;
a solid content of the first resin solution is 10%-50%;
a solid content of the second resin solution is 10%-35%;
the low-boiling solvent is selected from at least one of acetone, butanone, toluene, ethyl acetate, tetrahydrofuran, and chloroform;
the high-boiling solvent is selected from at least one of N,N-dimethylformamide, N,N-dimethylacetamide, and N-methylpyrrolidone;
the filler is selected from at least one of calcium carbonate, calcium phosphate, calcium pyrophosphate, calcium hydrogen phosphate, silicon carbide, carbon nanotubes, graphene, carbon black, silicon dioxide, and titanium dioxide;
the chemical imidization reagent includes a dehydrating agent, a catalyst, an imidization solvent, and an additive;
the dehydrating agent is selected from at least one of acetic anhydride, trifluoroacetic anhydride, benzoic anhydride, acetyl chloride, and thionyl chloride;
the catalyst is selected from at least one of quinoline, isoquinoline, pyridine, 3-methylpyridine, triethylamine, and N-methylimidazole;
the imidization solvent is selected from at least one of N,N-dimethylformamide, N,N-dimethylacetamide, and N-methylpyrrolidone;
the additive is selected from at least one of tricresyl phosphate, triphenyl phosphate, cresyldiphenyl phosphate, and trioctyl trimellitate;
the molecular weight reinforcing agent includes at least one of 1,2,4,5-benzenetetracarboxylic acid, 3,3′,4,4′-biphenyltetracarboxylic acid, tetrahydrofuran-2,3,4,5-tetracarboxylic acid, cyclohexane-1,2,4,5-tetracarboxylic acid, 1,2,3,4-cyclobutanetetracarboxylic acid, terephthalic acid, isophthalic acid, and terephthaloyl chloride;
a heating temperature of the high-temperature heating and biaxial stretching treatment in step 6) is 150° C.-600° C.
the molecular weight reinforcing agent further includes at least one of N,N-dimethylformamide, N,N-dimethylacetamide, and N-methylpyrrolidone.

For the preparation method as described above, in step 1), a molar ratio of the first aromatic dianhydride to the first aromatic diamine is 0.99:1 to 1.05:1; and/or,
a molar ratio of the second aromatic dianhydride to the second aromatic diamine is 0.8:1 to 0.995:1.

For the preparation method as described above, a solid content of the first resin solution is 30%-40%; and/or,
a solid content of the second resin solution is 25%-35%.

For the preparation method as described above, a mass of the chemical imidization reagent is 1%-30% of a mass of the second resin solution; and/or,
in the chemical imidization reagent, a molar ratio of the dehydrating agent to the catalyst is 1:2 to 5:1, a mass fraction of the imidization solvent is 10%-40%, and a mass fraction of the additive is 1%-10%; and/or,
an addition amount of the filler is 0.05%-5% of a total mass of the aromatic diamine and the aromatic dianhydride.

For the preparation method as described above, an amount of substance of the molecular weight reinforcing agent is equal to a difference in an amount of substance between the second aromatic diamine and the second aromatic dianhydride.

For the preparation method as described above, in step 5), the heating and drying treatment includes heating an upper surface and a lower surface of the initial composite gel film respectively, where a heating temperature of the upper surface is 50° C.-150° C., and a heating temperature of the lower surface is 80° C.-180° C.

For the preparation method as described above, in step 5), the heating and drying treatment performed on the initial composite gel film includes a second heating and drying treatment, a third heating and drying treatment, a fourth heating and drying treatment, a fifth heating and drying treatment, and a sixth heating and drying treatment that are performed in sequence;
the second heating and drying treatment has an upper-surface heating temperature of 80° C.-120° C., a lower-surface heating temperature of 120° C.-150° C., and a treatment time of 5 min-15 min;
the third heating and drying treatment has an upper-surface heating temperature of 90° C.-135° C., a lower-surface heating temperature of 135° C.-180° C., and a treatment time of 1 min-8 min;
the fourth heating and drying treatment has an upper-surface heating temperature of 80° C.-120° C., a lower-surface heating temperature of 120° C.-150° C., and a treatment time of 5 min-15 min;
the fifth heating and drying treatment has an upper-surface heating temperature of 60° C.-120° C., a lower-surface heating temperature of 120° C.-150° C., and a treatment time of 5 min-15 min;
the sixth heating and drying treatment has an upper-surface heating temperature of 50° C.-100° C., a lower-surface heating temperature of 100° C.-120° C., and a treatment time of 2 min-10 min.

For the preparation method as described above, in the stack heating treatment, the stack heating treatment has an upper-surface heating temperature of 60° C.-120° C., and a lower-surface heating temperature of 120° C.-180° C.

The present application also provides a circuit board, which includes any one of the foregoing polyimide films.

The present application also provides a gas barrier composite film, which includes any one of the foregoing polyimide films.

The present application also provides an insulating composite film, which includes any one of the foregoing polyimide films.

The polyimide film provided in the present application has the characteristics of large thickness, small linear thermal expansion coefficient, high pressure resistance and low gas permeability.

### BRIEF DESCRIPTION OF DRAWINGS

To describe the technical solutions in embodiments of the present application or in the prior art more clearly, the following will briefly introduce the accompanying drawings required for describing the embodiments or the prior art. Apparently, the accompanying drawings in the following description are merely some embodiments of the present application, and persons of ordinary skill in the art may still derive other drawings from these accompanying drawings without creative effort.

FIG. 1 is a structural diagram of a polyimide film production device.

### EXPLANATION OF REFERENCE SIGNS

101—first extrusion die head; 102—second extrusion die head; 103—mixer; 104—first heating driving-roller; 105—first heating driven-roller; 106—second heating driven-roller; 107—third heating driven-roller; 108—fourth heating driven-roller; 109—fifth heating driven-roller; 110—sixth heating driven-roller; 111—second heating driving-roller; A—first drying zone; B—second drying zone; C—third drying zone; D—fourth drying zone; E—fifth drying zone; F—sixth drying zone; G—seventh drying zone.

### DESCRIPTION OF EMBODIMENTS

To enable those skilled in the art to better understand the solutions of the present application, the present application is further described in detail below. The specific implementations listed below only describe the principles and features of the present application, and the examples provided are only used to explain the present application, not to limit the scope of the present application. Based on the embodiments of the present application, all other implementations obtained by those of ordinary skill in the art without making creative efforts shall fall within the protection scope of the present application.

A first aspect of the present application provides a polyimide film, where the polyimide film has a thickness of greater than or equal to 250 μm and includes a film layer A and at least one film layer B that are in contact with each other;
a surface roughness Rz of the film layer A is less than or equal to 1.0 μm;
the number of micropore with a size greater than 0.1 mm in the film layer B is less than or equal to 1 per square meter, a density of the film layer B is greater than or equal to 1.45 g/cm³, and a surface roughness Rz of the film layer B is greater than or equal to 1.2 μm.

The polyimide film provided by the present application is a multilayer film with a total thickness of greater than or equal to 250 μm and the number of layers of greater than or equal to two. This multilayer film includes two types of components, in which the first component forms the film layer A, and the second component forms the film layer B. Where, the number of layers of the film layer A is one, and the film layer A is located on one-side surface of the polyimide film; the number of layers of the film layer B is one or more, and the film layer A and the film layer B are in mutually fused contact in a stacked manner. Therefore, in one implementation, when the polyimide film has a two-layer structure, the layers from bottom to top are: film layer A and film layer B in sequence; when the polyimide film has a three-layer structure, the layers from bottom to top are: film layer A, first film layer B, second film layer B in sequence. The film layer B is the main component of a composite film, and the film layer A is a functional layer assisting in the manufacture of the film layer B. When the film layer A is formed, it is located between a support member (e.g., steel belt) and the film layer B, and has a small surface roughness after formation (its surface roughness Rz≤1.0 μm); the film layer B is located above the film layer A and in contact with air, and has a large surface roughness after formation (its surface roughness Rz≥1.2 μm). In the polyimide film provided by the present application, the number of micropores with a size greater than 0.1 mm in the film layer B is less than or equal to 1 per square meter, and a density of the film layer B is greater than or equal to 1.45 g/cm³.

The polyimide film provided by the present application has the characteristics of large thickness, small linear thermal expansion coefficient, high breakdown voltage, and low gas permeability.

Further, the polyimide film provided by the present application has a linear thermal expansion coefficient of 12 ppm/° C. to 35 ppm/° C., a breakdown voltage of greater than or equal to 30 kV, and a permeability to H₂ of less than or equal to 1.0×10⁻¹⁵ mol·m/m²·s·Pa; and a glass transition temperature of the film layer A is 180° C.-300° C.

In one implementation, a thickness of the film layer A accounts for 20%-50% of a total thickness of the polyimide film. The polyimide film meeting the above thickness percentage has more prominent characteristics of small linear thermal expansion coefficient, high breakdown voltage, and low gas permeability.

A second aspect of the present application provides a preparation method of the polyimide film, by which the polyimide film provided in the first aspect of the present application can be obtained. The method includes the following steps:
1) mixing a first aromatic dianhydride, a first aromatic diamine, a low-boiling solvent, a high-boiling solvent, and a filler, and allowing the first aromatic dianhydride and the first aromatic diamine to undergo a polycondensation reaction to obtain a first resin solution;
2) mixing a second aromatic dianhydride, a second aromatic diamine, a high-boiling solvent, and a filler, and allowing the second aromatic dianhydride and the second aromatic diamine to undergo a polycondensation reaction to obtain a second resin solution;
3) performing a first heating and drying treatment on a solution film formed by casting the first resin solution to obtain an initial film layer A;
4) mixing the second resin solution with a chemical imidization reagent and a molecular weight reinforcing agent to obtain a second resin mixed solution; performing at least one stack heating treatment on the initial film layer A using the second resin mixed solution to obtain an initial composite gel film;
5) sequentially performing at least one heating and drying treatment on the initial composite gel film to obtain an intermediate composite gel film;
6) performing a high-temperature heating and biaxial stretching treatment on the intermediate composite gel film to obtain the polyimide film;
where, the first heating and drying treatment has a treatment temperature of 50° C.-120° C., and a treatment time of 2 min-10 min;
the stack heating treatment includes attaching the second resin mixed solution to one-side surface of the initial film layer A, and performing a heating treatment at a temperature of 60° C.-150° C. for a time of 5 min-15 min;
the heating and drying treatment for the initial composite gel film has a treatment temperature of 50° C.-180° C., and a treatment time of 18 min-60 min;
the first aromatic dianhydride is selected from at least one of pyromellitic dianhydride, 3,3′,4,4′-biphenyltetracarboxylic dianhydride, 2,3,3′,4-biphenyltetracarboxylic dianhydride, 4,4′-oxydiphthalic dianhydride, 3,4,3′,4′-triphenyl diether dianhydride, 2,2-bis[4-(3,4-dicarboxyphenoxy)phenyl]propane dianhydride, 2,2-diphenylpropane-3,4,3′,4′-tetracarboxylic dianhydride, 3,3′,4,4′-benzophenonetetracarboxylic dianhydride, 3,3′,4,4′-diphenyl sulfone tetracarboxylic dianhydride, and p-phenylene-bis-trimellitate dianhydride;
the first aromatic diamine is selected from at least one of 4,4′-diaminodiphenyl ether, 2,2-bis[4-(4-aminophenoxy)phenyl]propane, 4,4′-diaminodiphenylmethane, 2,2-bis(4-aminophenyl)propane, 1,3-bis(3-aminophenoxy)benzene, 1,4-bis(4-aminophenoxy)benzene, 2,4-diaminotoluene, and 1,3-bis(aminopropyl)tetramethyldisiloxane;
the second aromatic dianhydride is selected from at least one of pyromellitic dianhydride and 3,3′,4,4′-biphenyltetracarboxylic dianhydride;
the second aromatic diamine is selected from at least one of 4,4′-diaminodiphenyl ether and 1,4-phenylenediamine;
a solid content of the first resin solution is 10%-50%;
a solid content of the second resin solution is 10%-35%;
the low-boiling solvent is selected from at least one of acetone, butanone, toluene, ethyl acetate, tetrahydrofuran, and chloroform;
the high-boiling solvent is selected from at least one of N,N-dimethylformamide, N,N-dimethylacetamide, and N-methylpyrrolidone;
the filler is selected from at least one of calcium carbonate, calcium phosphate, calcium pyrophosphate, calcium hydrogen phosphate, silicon carbide, carbon nanotubes, graphene, carbon black, silicon dioxide, and titanium dioxide;
the chemical imidization reagent includes a dehydrating agent, a catalyst, an imidization solvent, and an additive;
the dehydrating agent is selected from at least one of acetic anhydride, trifluoroacetic anhydride, benzoic anhydride, acetyl chloride, and thionyl chloride;
the catalyst is selected from at least one of quinoline, isoquinoline, pyridine, 3-methylpyridine, triethylamine, and N-methylimidazole;
the imidization solvent is selected from at least one of N,N-dimethylformamide, N,N-dimethylacetamide, and N-methylpyrrolidone;
the additive is selected from at least one of tricresyl phosphate, triphenyl phosphate, cresyldiphenyl phosphate, and trioctyl trimellitate;
the molecular weight reinforcing agent includes at least one of 1,2,4,5-benzenetetracarboxylic acid, 3,3′,4,4′-biphenyltetracarboxylic acid, tetrahydrofuran-2,3,4,5-tetracarboxylic acid, cyclohexane-1,2,4,5-tetracarboxylic acid, 1,2,3,4-cyclobutanetetracarboxylic acid, terephthalic acid, isophthalic acid, and terephthaloyl chloride;
a heating temperature of the high-temperature heating and biaxial stretching treatment in step 6) is 150° C.-600° C.

Specifically, in step 1), the first aromatic dianhydride and the first aromatic diamine are used for a polycondensation reaction. The present application does not limit the types and quantities of the first aromatic dianhydride and the first aromatic diamine; both the first aromatic dianhydride and the first aromatic diamine may be selected from one or more types.

The low-boiling solvent refers to a solvent with a boiling point range of 55° C. to 120° C., and is selected from at least one of acetone, butanone, toluene, ethyl acetate, tetrahydrofuran, and chloroform; the high-boiling solvent refers to a solvent with a boiling point range of 150° C. to 230° C., and is selected from at least one of N,N-dimethylformamide, N,N-dimethylacetamide, and N-methylpyrrolidone. The cooperation between the low-boiling solvent and the high-boiling solvent results in a solvent that is easy to be removed during the heating and drying treatment, which can achieve the design object of controlling the total volatilization amount of solvent from an front end of coating, significantly reduce the size shrinkage of the gel film caused by solvent volatilization, and alleviate the occurrence of the “surface drying phenomenon” (that is, during the heating and drying treatment, the surface layer of the object to be treated dries before the inner layer, making it difficult for the solvent in the inner layer to volatilize).

The present application does not limit the ratio of the low-boiling solvent to the high-boiling solvent; in one embodiment, the mass ratio of the low-boiling solvent to the high-boiling solvent is 20:100 to 40:100.

The chemical imidization reagent may convert polyamic acid into polyimide at a low temperature. The chemical imidization reagent includes a dehydrating agent, a catalyst, an imidization solvent, and an additive.

Where, the dehydrating agent is selected from at least one of acetic anhydride, trifluoroacetic anhydride, benzoic anhydride, acetyl chloride, and thionyl chloride; the catalyst is selected from at least one of quinoline, isoquinoline, pyridine, 3-methylpyridine, triethylamine, and N-methylimidazole; the imidization solvent is selected from at least one of N,N-dimethylformamide, N,N-dimethylacetamide, and N-methylpyrrolidone; the additive is selected from at least one of tricresyl phosphate, triphenyl phosphate, cresyldiphenyl phosphate, and trioctyl trimellitate; the molecular weight reinforcing agent includes at least one of 1,2,4,5-benzenetetracarboxylic acid, 3,3′,4,4′-biphenyltetracarboxylic acid, tetrahydrofuran-2,3,4,5-tetracarboxylic acid, cyclohexane-1,2,4,5-tetracarboxylic acid, 1,2,3,4-cyclobutanetetracarboxylic acid, terephthalic acid, isophthalic acid, and terephthaloyl chloride. The molecular weight reinforcing agent can be dissolved in a solvent, and the solvent can be selected from at least one of N,N-dimethylformamide, N,N-dimethylacetamide, and N-methylpyrrolidone.

The present application does not limit the ratio of the dehydrating agent, catalyst, solvent, and additive; in one implementation, the mass ratio of the dehydrating agent, catalyst, solvent, and additive is 1099:501:400:100.

Further, the function of the filler is to improve the opening performance of the polyimide film, which can achieve the technical effects of antistatic electricity and anti-adhesion. The molecular weight reinforcing agent functions to perform chain extension on the polyimide molecules during the production of the polyimide film, thereby increasing the molecular weight of the polyimide.

The present application does not limit the specific implementation method of step 1), as long as it can satisfy the requirement of enabling the first aromatic dianhydride and the first aromatic diamine to undergo a polycondensation reaction to obtain the first resin solution. Specifically, in step 1), the first resin solution can be prepared by any one of the following methods:
a) under the protection of an inert gas, sequentially adding the low-boiling solvent and the high-boiling solvent into a reaction kettle; starting stirring; adding the filler into the reaction kettle and stirring; slowly adding the first aromatic diamine into the reaction kettle to dissolve it under stirring; slowly adding the first aromatic dianhydride into the reaction kettle; allowing the first aromatic dianhydride and the first aromatic diamine to undergo a polymerization reaction for a period of time to obtain a first resin solution; and freezing and storing the first resin solution at a low temperature, where in this solution, the molecular structure of resin is a polymer of one type of first aromatic diamine and one type of first aromatic dianhydride;
b) under the protection of an inert gas, sequentially adding the low-boiling solvent and the high-boiling solvent into the reaction kettle; starting stirring; adding the filler into the reaction kettle and stirring; slowly adding the first type of first aromatic diamine into the reaction kettle and stirring; slowly adding the first type of first aromatic dianhydride into the reaction kettle; performing the first polymerization; after reacting for a period of time, slowly adding the second type of first aromatic dianhydride into the reaction kettle to perform the second polymerization; adding the third or more types of first aromatic dianhydrides shall be carried out and reacted according to the feeding method of the second type of first aromatic dianhydride and reacting, and finally obtaining a first resin solution; and freezing and storing the first resin solution at a low temperature, where in this solution, the molecular structure of resin is a random copolymer of one type of first aromatic diamine and two or more types of first aromatic dianhydrides;
c) under the protection of an inert gas, sequentially adding the low-boiling solvent and the high-boiling solvent into the reaction kettle; starting stirring; adding the filler into the reaction kettle and stir; slowly adding the first type of first aromatic diamine into the reaction kettle and stirring; slowly adding the first type of first aromatic dianhydride into the reaction kettle; performing the first polymerization; after reacting for a period of time, slowly adding the second type of first aromatic diamine into the reaction kettle to perform the second polymerization; after reacting for a period of time, slowly adding the second type of first aromatic dianhydride into the reaction kettle to perform the third polymerization; after reacting for a period of time, obtaining a first resin solution; and freezing and storing the first resin solution at a low temperature, where, in this solution, the molecular structure of resin is a block copolymer of two types of first aromatic diamines and two types of first aromatic dianhydrides; and block copolymers of two or more types of first aromatic diamines and two or more types of first aromatic dianhydrides can be prepared by this method;
d) under the protection of an inert gas, adding the low-boiling solvent and the high-boiling solvent into the reaction kettle; starting stirring; adding the filler into the reaction kettle and stir; slowly adding two or more types of first aromatic diamines into the reaction kettle and stirring; slowly adding one type of first aromatic dianhydride into the reaction kettle; performing the polymerization reaction for a period of time to obtain a first resin solution; and freezing and storing the first resin solution at a low temperature; where, in this solution, the molecular structure of resin is a random copolymer of one type of first aromatic dianhydride and two or more types of first aromatic diamines;
e) under the protection of an inert gas, adding the low-boiling solvent and the high-boiling solvent into the reaction kettle; starting stirring; adding the filler into the reaction kettle and stirring; slowly adding the first type of first aromatic diamine into the reaction kettle and stirring; slowly adding the first type of first aromatic dianhydride into the reaction kettle; performing the first polymerization; after reacting for a period of time, slowly adding the second type of first aromatic diamine into the reaction kettle to perform the second polymerization; adding the third or more types of first aromatic diamines according to the feeding method of the second type of first aromatic diamine and reacting, and finally obtaining a first resin solution; and freezing and storing the first resin solution at a low temperature; where, in this solution, the molecular structure of resin is a block copolymer of one type of first aromatic dianhydride and two or more types of first aromatic diamines.

That is, the first resin solution includes but is not limited to: a block copolymer or random copolymer of one type of first aromatic dianhydride with one type of first aromatic diamine or two or more types of first aromatic diamines; a block copolymer or random copolymer of one type of first aromatic diamine with one type of first aromatic dianhydride or two or more types of first aromatic dianhydrides; a block copolymer or random copolymer of two or more types of first aromatic dianhydrides with two or more types of first aromatic diamines.

In step 2), the second aromatic dianhydride and the second aromatic diamine are used for the polycondensation reaction. The present application does not limit the types and quantities of the second aromatic dianhydride and the second aromatic diamine; both the second aromatic dianhydride and the second aromatic diamine can be selected from one or more types.

The present application does not limit the specific implementation method of step 2), as long as it can satisfy the requirement of enabling the second aromatic dianhydride and the second aromatic diamine to undergo a polycondensation reaction to obtain the second resin solution. Specifically, in step 2), the second resin solution can be prepared by the same method as step 1).

The second resin solution includes but is not limited to a block copolymer or random copolymer of one type of second aromatic dianhydride with one type of second aromatic diamine or two types of second aromatic diamines, a block copolymer or random copolymer of one type of second aromatic diamine with one type of second aromatic dianhydride or two types of second aromatic dianhydrides, and a block copolymer or random copolymer of two types of second aromatic dianhydrides with two types of second aromatic diamines.

Further, in step 3), a first heating and drying treatment is performed on the solution film formed by casting the first resin solution, obtaining the initial film layer A. During the first heating and drying treatment, the solvent in the first resin solution volatilizes at a high temperature, and other components in the first resin solution form the initial film layer A in a solid state. The first heating and drying treatment has a treatment temperature of 50° C.-120° C., and a treatment time of 2 min-10 min. The above treatment conditions may make the solvent in the solution film formed by casting the first resin solution volatilize at an appropriate rate, forming the initial film layer A.

It can be understood that to facilitate the drying of the solution film formed by casting the first resin solution, in one implementation, the first resin solution may be extruded and cast into a suitable shape onto a support member, and then the extruded first resin solution on the support member is subjected to the first heating and drying treatment to obtain the initial film layer A. The present application does not limit the specific structure of the support member, as long as it can support the extruded and cast resin solution. In one implementation, the support member is a steel belt.

Further, in one implementation, the first heating and drying treatment is used for heating the upper surface and the lower surface of the extruded first resin solution respectively, with the heating temperature of the upper surface being 80° C. and the heating temperature of the lower surface being 100° C. Where, the upper surface refers to a side surface of the extruded first resin solution that is not in contact with the support member, and the lower surface refers to a side surface of the extruded first resin solution that is in contact with the support member. Heating the upper surface and the lower surface of the extruded first resin solution at different temperatures can guide the organic volatile components in the gel film to evaporate uniformly vertically outward from the side of the support member, which can effectively regulate the solvent content of the gel film and achieve the technical effect of avoiding the “surface drying” problem.

Further, in step 4), at least one stack heating treatment is performed on the initial film layer A using the second resin mixed solution obtained by mixing the second resin solution with the chemical imidization reagent and the molecular weight reinforcing agent, so as to obtain the initial composite gel film. Specifically, the stack heating treatment includes attaching the second resin mixed solution to one-side surface of the initial film layer A, and performing a heating treatment at a temperature of 60° C.-150° C. for 5 min-15 min, so that the organic volatile components in the second resin mixed solution in contact with the upper surface of the initial film layer A evaporate slowly and form a film; at the same time, the chemical imidization reagent and the molecular weight reinforcing agent included in the second resin mixed solution react with the second resin solution, allowing the film layer formed by the second resin mixed solution to have a higher mechanical strength.

Thus, the above treatment finally obtains the initial composite gel film. The initial composite gel film includes the initial film layer A and a film layer formed by drying the second resin mixed solution.

Further, the above stack heating treatment may be performed multiple times. That is, in the first stack heating treatment, the second resin mixed solution is extruded onto the upper surface of the initial film layer A and then heated to form a film (referred to as a freshly formed film); subsequently, the second resin mixed solution is extruded again onto the surface of the freshly formed film facing away from the initial film layer A and then heated, forming an initial composite gel film with a three-layer structure.

The present application does not limit the specific number of times the above stack heating treatment is performed; the specific number of times can be determined according to the number of layers of the initial composite gel film required to be obtained, and the specific number of times is one less than the number of layers of the initial composite gel film required to be obtained. For example, if the number of layers of the initial composite gel film required to be obtained is 2, the specific number of times the stack heating treatment is performed is 1; if the number of layers of the initial composite gel film required to be obtained is 3, the specific number of times the stack heating treatment is performed is 2, and so on.

Further, at least one heating and drying treatment is sequentially performed on the initial composite gel film to obtain an intermediate composite gel film. During the heating and drying treatment, the solvent contained in the initial composite gel film continues to volatilize, and the chemical imidization reagent, the molecular weight reinforcing agent, and other components contained in the second resin solution continue to react to obtain the intermediate composite gel film; the polyimide film provided by the present application can be obtained by performing a biaxial stretching treatment (including transverse stretching treatment and longitudinal stretching treatment) on the intermediate composite gel film.

For each heating and drying treatment, the treatment temperature is 50° C.-180° C., and the treatment time is 18 min-60 min. The present application does not limit the specific number of heating and drying treatments, which can be determined according to requirements.

Further, a solid content of the first resin solution is 10%-50%, and a solid content of the second resin solution is 10%-35%. The solid content of the first resin solution refers to a ratio of a total mass of the first aromatic dianhydride, the first aromatic diamine and the filler to a mass of the first resin solution; the solid content of the second resin solution refers to a ratio of a total mass of the second aromatic dianhydride, the second aromatic diamine and the filler to a mass of the second resin solution.

The first resin solution has the characteristic of high adhesion. The initial film layer A prepared by casting and drying is located at the bottom layer and is in direct contact with the support member, which can not only greatly improve the adhesion to the support member but also stably support the weight of the subsequent stacked gel film, effectively solving the problem of belt detachment caused by insufficient adhesion between the ultra-thick gel film and the support member.

The gel film prepared from the second resin solution is located above the initial film layer A and is not in direct contact with the support member, avoiding the problems of shrinkage and belt detachment caused by insufficient adhesion to the support member. The second resin solution reacts with the chemical imidization reagent and, in combination with the action of the molecular weight reinforcing agent, enables the preparation of a gel film with high mechanical properties and solves the tearing problem caused by insufficient mechanical properties during the production of the gel film.

Further, both the first resin solution and the second resin solution have high solid contents, which can control the initial organic volatile components of the cast gel film at a low mass ratio, and significantly reduce the evaporation amount of organic volatile components per unit time. It not only helps control the shrinkage size of the gel film and avoid the problem of belt detachment, but also helps reduce the number of internal hole defects of the gel film caused by the evaporation of organic volatile components. This enables the preparation of an intermediate gel film with controllable solvent content and high mechanical properties, thereby improving the density of the polyimide film, and reducing the linear thermal expansion coefficient and gas permeability of the polyimide film.

Both the first resin solution and the second resin solution used in the preparation method of the polyimide film provided by the present application have the characteristic of high solid content. Where, the first resin solution contains both a high-boiling solvent and a low-boiling solvent, so it has the characteristic that the solvent is easy to be removed during the heating and drying treatment. This can reduce the solvent content of the inner layer of the gel film, not only alleviating the “surface drying” phenomenon but also reducing the shrinkage size of the support layer gel film during drying to prevent belt detachment.

Further, the first resin solution also has the characteristic of high adhesion. The initial film layer A prepared by the first heating and drying treatment is located at the bottom layer and is in direct contact with the support member, which can not only greatly improve its adhesion to the support member but also stably support the weight of the subsequent stacked gel film, effectively solving the problem of belt detachment caused by insufficient adhesion between the ultra-thick gel film and the steel belt. Further, the gel films of the second and upper layers prepared from the second resin solution are located above the initial film layer A and are not in direct contact with the support member, avoiding the problems of shrinkage and belt detachment caused by insufficient adhesion to the support member. The second resin solution reacts with the chemical imidization reagent and, in combination with the action of the molecular weight reinforcing agent, enables the preparation of a gel film with high mechanical properties and also solves the tearing problem due to insufficient mechanical properties during the production of the gel film.

In one implementation, the heating temperature of the high-temperature heating and biaxial stretching treatment in step 6) may be controlled to 150° C.-600° C. The above treatment conditions can make the intermediate composite gel film stretch more uniformly to prepare the polyimide film.

In one implementation, in step 1), the molar ratio of the first aromatic dianhydride to the first aromatic diamine is 0.99:1 to 1.05:1; in an implementation, the molar ratio of the first aromatic dianhydride to the first aromatic diamine is 0.995:1 to 1.02:1. Further, the molar ratio of the second aromatic dianhydride to the second aromatic diamine is 0.8:1 to 0.995:1; in an implementation, the molar ratio of the second aromatic dianhydride to the second aromatic diamine is 0.88:1 to 0.98:1. Controlling the aromatic dianhydride and the aromatic diamine to meet the above molar ratio for polycondensation reaction can accurately synthesize a polyamic acid resin solution with a certain viscosity.

Further, in one implementation, the solid content of the first resin solution is 30%-40%; further, the solid content of the second resin solution is 25%-35%. The high solid content characteristics of the above first resin solution and second resin solution may control the total amount of organic volatile components from the front end of coating, significantly reduce the size shrinkage of the gel film caused by solvent volatilization, and alleviate the “surface drying” phenomenon, which can not only realize the stable preparation of the intermediate composite gel film but also be conductive to obtaining a high-quality polyimide film with few internal “hole” defects.

In one implementation, the mass of the chemical imidization reagent is 1%-30% of the mass of the second resin solution; in an implementation, the mass of the chemical imidization reagent is 5%-15% of the mass of the second resin solution. Further, the molar ratio of the dehydrating agent to the catalyst in the chemical imidization reagent is 1:2 to 5:1, in a further implementation, the molar ratio of the dehydrating agent to the catalyst in the chemical imidization reagent is 2:1; the mass fraction of the imidization solvent is 10%-40%, in a further implementation, the mass fraction of the imidization solvent is 20%; the mass fraction of the additive is 1%-10%, in a further implementation, the mass fraction of the additive is 5%. Further, the mass of the filler is 0.05%-5% of the total mass of the aromatic diamine and the aromatic dianhydride, in a further implementation, the mass of the filler is 0.1% of the total mass of the aromatic diamine and the aromatic dianhydride. The addition amount of the above chemical imidization reagent may convert polyamic acid into polyimide at a low temperature through the chemical imidization method, and the prepared polyimide film has the advantages of high tensile strength and small linear thermal expansion coefficient.

Further, in one implementation, the amount of substance of the molecular weight reinforcing agent is equal to a difference in the amount of substance between the second aromatic diamine and the second aromatic dianhydride. When the amount of substance of the molecular weight reinforcing agent meets the above condition, the mechanical properties of the prepared polyimide film can be improved by increasing the molecular weight of the polyimide.

In one implementation, in step 5), the heating and drying treatment includes heating the upper surface and the lower surface of the initial composite gel film respectively, where the heating temperature of the upper surface is 50° C.-150° C., and the heating temperature of the lower surface is 80° C.-180° C. Where, the upper surface refers to a surface of the initial composite gel film that is subjected to the stack heating treatment. The lower surface refers to a surface of the initial composite gel film that is not subjected to the stack heating treatment, that is, the surface in contact with the support member. Heating the upper surface and the lower surface of the initial composite gel film respectively can guide the organic volatile components in the gel film to evaporate uniformly vertically outward from the side of the support member, which can effectively regulate the solvent content of the gel film and avoid the “surface drying” problem.

Further, in one implementation, in step 5), the heating and drying treatment performed on the initial composite gel film includes a second heating and drying treatment, a third heating and drying treatment, a fourth heating and drying treatment, a fifth heating and drying treatment, and a sixth heating and drying treatment that are performed in sequence;
the second heating and drying treatment has an upper-surface heating temperature of 80° C.-120° C., a lower-surface heating temperature of 120° C.-150° C., and a treatment time of 5 min-15 min;
the third heating and drying treatment has an upper-surface heating temperature of 90° C.-135° C., a lower-surface heating temperature of 135° C.-180° C., and a treatment time of 1 min-8 min;
the fourth heating and drying treatment has an upper-surface heating temperature of 80° C.-120° C., a lower-surface heating temperature of 120° C.-150° C., and a treatment time of 5 min-15 min;
the fifth heating and drying treatment has an upper-surface heating temperature of 60° C.-120° C., a lower-surface heating temperature of 120° C.-150° C., and a treatment time of 5 min-15 min;
the sixth heating and drying treatment has an upper-surface heating temperature of 50° C.-100° C., a lower-surface heating temperature of 100° C.-120° C., and a treatment time of 2 min-10 min.

Heating the upper surface and the lower surface of the initial composite gel film respectively under the foregoing conditions can guide the organic volatile components in the gel film to evaporate uniformly vertically outward from the side of the support member, effectively regulating the solvent content in the gel film, and avoiding the “surface drying” problem.

Further, in one implementation, in the stack heating treatment, an upper-surface heating temperature of the heating treatment is 60° C.-120° C., and a lower-surface heating temperature of the heating treatment is 120° C.-180° C. Where, the lower surface refers to a surface of the initial film layer A in contact with the support member, and the upper surface refers to a surface loaded with the second resin mixed solution. The foregoing treatment conditions can guide the organic volatile components in the gel film to evaporate uniformly vertically outward from the side of the support member, effectively regulating the solvent content in the gel film, and avoiding the “surface drying” problem.

A third aspect of the present application provides a circuit board, which includes the polyimide film provided in the first aspect of the present application. Further, in one implementation, the circuit board is a flexible circuit board, and the polyimide film provided in the first aspect of the present application serves as a base material of the flexible circuit board. Since the polyimide film provided in the first aspect of the present application has a linear thermal expansion coefficient of 12 ppm/° C.-35 ppm/° C., the circuit board has the characteristic of high dimensional stability.

A fourth aspect of the present application provides a gas barrier composite film, which is the polyimide film provided in the first aspect of the present application or includes the polyimide film provided in the first aspect of the present application. Further, in one implementation, the gas barrier composite film is a lining material for hydrogen transmission pipelines, and the polyimide film provided in the first aspect of the present application serves as the lining material or a part of the lining material. Since the polyimide film provided in the first aspect has a permeability to H₂ of ≤1.0×10⁻¹⁵ mol·m/m²·s·Pa, the gas barrier composite film has the characteristic of high gas barrier property.

A fifth aspect of the present application provides an insulating composite film, which includes the polyimide film provided in the first aspect of the present application. Further, in one implementation, the insulating composite film is an insulating layer of a high-voltage resistant cable, and the polyimide film provided in the first aspect of the present application serves as a part of the insulating layer. Since the polyimide film provided in the first aspect has a breakdown voltage of ≥30 kV, the insulating composite film has the characteristic of high insulation.

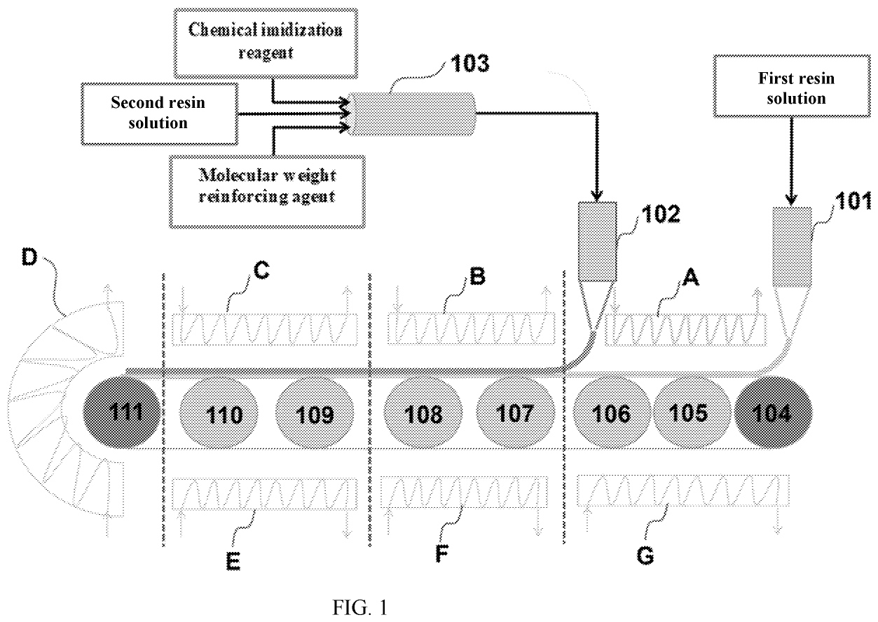

FIG. 1 is a device for implementing the preparation method of the polyimide film provided in the second aspect of the present application. As shown in FIG. 1, the device includes 101—first extrusion die head, 102—second extrusion die head, 103—mixer, 104—first heating driving-roller, 105—first heating driven-roller, 106—second heating driven-roller, 107—third heating driven-roller, 108—fourth heating driven-roller, 109—fifth heating driven-roller, 110—sixth heating driven-roller, 111—second heating driving-roller, A—first drying zone (hereinafter referred to as Zone A), B—second drying zone (hereinafter referred to as Zone B), C—third drying zone (hereinafter referred to as Zone C), D—fourth drying zone (hereinafter referred to as Zone D), E—fifth drying zone (hereinafter referred to as Zone E), F—sixth drying zone (hereinafter referred to as Zone F), G-seventh drying zone (hereinafter referred to as Zone G).

Where, 101—first extrusion die head is configured to cast the first resin solution to form a solution film; 103—mixer is configured to mix the chemical imidization reagent, the second resin solution and the molecular weight reinforcing agent to obtain a second resin mixed solution, which then enters 102—second extrusion die head; 102—second extrusion die head extrudes the second resin mixed solution to perform at least one stack heating treatment on the initial film layer A.

104—first heating driving-roller, 105—first heating driven-roller, 106—second heating driven-roller, 107—third heating driven-roller, 108—fourth heating driven-roller, 109—fifth heating driven-roller, 110—sixth heating driven-roller, and 111—second heating driving-roller are moving structures with a steel belt attached to respective outer surface, which can make the steel belt rotate counterclockwise around the above moving structures.

A—first drying zone (hereinafter referred to as Zone A), B—second drying zone (hereinafter referred to as Zone B), C—third drying zone (hereinafter referred to as Zone C), D—fourth drying zone (hereinafter referred to as Zone D), E—fifth drying zone (hereinafter referred to as Zone E), F—sixth drying zone (hereinafter referred to as Zone F), and G-seventh drying zone (hereinafter referred to as Zone G) are heating plates with internal heat sources, which are provided around the steel belt for performing heating and drying treatment.

The process of using the above device for polyimide film production is as follows: the first extrusion die head 101 extrudes the first resin solution onto the steel belt to cast it into a solution film; the first drying zone A, the first heating driving-roller 104, the first heating driven-roller 105, and the second heating driven-roller 106 are respectively located on an upper surface and lower surface of the solution film to perform the first heating and drying treatment, so as to obtain an initial film layer A; when the initial film layer A moves counterclockwise to directly below 102—second extrusion die head, 102—second extrusion die head extrudes the second resin mixed solution; the solution film formed by casting the solution covers the upper surface of the initial film layer A and moves to below B—second drying zone and above 107—third heating driven-roller and 108—fourth heating driven-roller for heating. The above process is also that the initial film layer A is subjected to one stack heating treatment using the second resin mixed solution to obtain the initial composite gel film.

The initial composite gel film moves counterclockwise and undergoes the second heating and drying treatment below C—third drying zone and above 109—fifth heating driven-roller and 110—sixth heating driven-roller, and so on; after the sixth heating and drying treatment is done above G-seventh drying zone and below the first heating driving-roller 104, 105—first heating driven-roller and 106—second heating driven-roller, the intermediate composite gel film is obtained. The intermediate composite gel film is longitudinally stretched at room temperature, transversely stretched at 150° C.-600° C., and cooled to obtain the polyimide film.

The present application also provides a standard for solvent content and tensile strength of an intermediate composite gel film for producing polyimide films. Where, the solvent content and tensile strength of the intermediate composite gel film meet the standards shown in Table 1, and the intermediate composite gel film is subjected to biaxial stretching and high-temperature treatment to produce polyimide films of corresponding thicknesses. Solvent content of the composite gel film=[(total weight of the composite gel film-weight of the composite gel film dried at high temperature)/weight of the composite gel film dried at high temperature]×100%; the weight of the composite gel film dried at high temperature refers to a weight of the composite gel film after being dried at 450° C. for 2 hours; the tensile strength of the intermediate composite gel film is detected by an Instron 68SC-05 universal tensile machine.

TABLE 1
Standard for solvent content and tensile strength of intermediate
composite gel film for producing ultra-thick polyimide film

| | Solvent | Tensile | Stacked structure and thickness of | | | |
|---|---|---|---|---|---|---|
| | content of | strength of | ultra-thick polyimide composite film (μm) | | | |
| | intermediate | intermediate | Thickness | Thickness | Thickness | Total |
| | composite | composite | of layer | of layer | of layer | thickness |
| No. | gel film (%) | gel film (MPa) | 1 (μm) | 2 (μm) | 3 (μm) | (μm) |
| 1 | 80-120 | ≥45 | 48-52 | 185-215 | — | 243-257 |
| 2 | 95-145 | ≥50 | 76-84 | 202-238 | — | 288-312 |
| 3 | 110-160 | ≥55 | 76-84 | 245-280 | — | 331-369 |
| 4 | 125-185 | ≥60 | 95-108 | 280-320 | — | 385-415 |
| 5 | 150-210 | ≥70 | 95-108 | 321-379 | — | 436-474 |
| 6 | 170-235 | ≥80 | 141-159 | 321-379 | — | 479-528 |
| 7 | 185-270 | ≥95 | 141-159 | 380-440 | — | 531-579 |
| 8 | 200-290 | ≥110 | 185-215 | 380-440 | — | 580-625 |
| 9 | 230-315 | ≥130 | 185-215 | 141-179 | 280-320 | 632-683 |
| 10 | 265-335 | ≥150 | 200-240 | 141-179 | 321-379 | 692-736 |

Hereinafter, the polyimide film and its preparation method provided in the present application are further introduced through various examples.

### Example 1

This example uses the following method and the device shown in FIG. 1 to prepare a polyimide film.

### 1) Preparation of a First Resin Solution

Under the protection of nitrogen, 3139 g N,N-dimethylformamide (DMF) and 1046 g tetrahydrofuran (THF) are added into a 15 L reaction kettle followed by stirring; 124 3 g 4,4′-bis(4-aminophenoxy)biphenyl (BAPP) and 606 g 3,4′-oxydianiline (3,4-ODA) are weighted and added sequentially into the reaction kettle, and stirred at room temperature for 30 min; 3 g calcium pyrophosphate is weighed and added into the reaction kettle and stirred for 20 min; 1880 g 4,4′-oxydiphthalic anhydride (ODPA) is weighed and slowly added into the reaction kettle and stirred for 300 min to obtain the first resin solution with a solid content of 47% and a viscosity of 1815P; and the obtained first resin solution is frozen and stored at −10° C. for later use.

### 2) Preparation of a Second Resin Solution

Under the protection of nitrogen, 10484 g DMF is added into a 20 L reaction kettle and stirred; 1170 g 4,4′-oxydianiline (ODA) and 632 g p-phenylenediamine (PDA) are weighted and added into the reaction kettle and stirred at room temperature for 30 min; 3 g calcium pyrophosphate is weighed and added into the reaction kettle and stirred for 20 min; 1174 g pyromellitic dianhydride (PMDA) and 1514 g 3,3′,4,4′-Biphenyltetracarboxylic dianhydride (s-BPDA) are weighted and added slowly into the reaction kettle sequentially and stirred for 300 min to obtain the second polyamic acid resin solution with a solid content of 30% and a viscosity of 2005P; and the obtained second polyamic acid resin solution is frozen and stored at −10° C. for later use.

3) Preparation of a Polyimide Composite Film with a Two-Layer Structure

\textcircled{1} Preparation of a chemical imidization reagent: under the protection of nitrogen, 800 g DMF, 2198 g acetic anhydride, 1002 g 3-methylpyridine, and 200 g triphenyl phosphate are added sequentially into a 5 L reaction kettle, and stirred for 180 min for later use.

\textcircled{2} Preparation of a molecular weight reinforcing agent: under the protection of nitrogen, 1200 g DMF and 600 g 1,2,4,5-benzenetetracarboxylic acid are added sequentially into a 2 L reaction kettle, and stirred at 60° C. for 120 min for later use.

\textcircled{3} The first resin solution is pumped into a first extrusion die head and cast onto the surface of a steel belt; a first-layer gel film travels with the steel belt in Zone A and undergoes the first heating and drying treatment to obtain an initial film layer A.

The chemical imidization reagent and molecular weight reinforcing agent from \textcircled{1} and \textcircled{2}, as well as the second resin solution are quantitatively pumped into a mixer and fully mixed to obtain a second resin mixed solution; the second resin mixed solution is pumped into a second extrusion die head; the second resin mixed solution is cast onto the upper surface of the initial film layer A and heated in Zone B to obtain an initial composite gel film with a two-layer structure (that is, one stack heating treatment is performed on the initial film layer A using the second resin mixed solution).

The initial composite gel film travels with the steel belt, undergoing the second drying treatment in Zone C, the third drying treatment in Zone D, the fourth drying treatment in Zone E, the fifth drying treatment in Zone F, and the sixth drying treatment in Zone G, to obtain an intermediate composite gel film with a certain solvent content and mechanical properties. The intermediate composite gel film is longitudinally stretched at room temperature, then transversely stretched at 150° C.-600° C. and cooled to obtain a polyimide film with a thickness of 252 μm.

The quantitative relationship among the first resin solution, the second resin solution, the chemical imidization reagent, and the molecular weight reinforcing agent is shown in Table 2.

TABLE 2

| | First extrusion | Second extrusion die head | | |
|---|---|---|---|---|
| | die head | | Molecular | |
| | First | Second | weight | Chemical |
| | resin | resin | reinforcing | imidization |
| Name | solution | solution | agent | reagent |
| Feeding flow | 125 | 666 | 27 | 80 |
| rate (g/min) | | | | |

Specifically, in Example 1, the treatment time, air-side temperature (upper-surface heating temperature), and steel belt-side temperature (lower-surface heating temperature) of the Zone A (first heating and drying treatment), the Zone B (first stack heating treatment), the Zone C (second heating and drying treatment), the Zone D (third heating and drying treatment), the Zone E (fourth heating and drying treatment), the Zone F (fifth heating and drying treatment), and the Zone G (sixth heating and drying treatment) are shown in Table 3.

TABLE 3

| | Zone | Zone | Zone | Zone | Zone | Zone | Zone |
|---|---|---|---|---|---|---|---|
| Name | A | B | C | D | E | F | G |
| Time (min) | 4.5 | 6 | 6 | 3 | 6 | 6 | 4.5 |
| Air-Side | 80 | 85 | 100 | 105 | 100 | 85 | 80 |
| Temperature (° C.) | | | | | | | |
| Steel Belt-Side | 100 | 120 | 135 | 160 | 135 | 120 | 100 |
| Temperature (° C.) | | | | | | | |

### Examples 2-8

Examples 2-8 are basically the same as Example 1, except that the feeding flow rates of the first extrusion die head and the second extrusion die head are different. The specific feeding flow rate data are shown in Table 4.

TABLE 4

| | Feeding Flow Rate (g/min) | | | |
|---|---|---|---|---|
| | First extrusion | Second extrusion die head | | |
| | die head | | Molecular | |
| | First | Second | weight | Chemical |
| | resin | resin | reinforcing | imidization |
| Name | solution | solution | agent | reagent |
| Example 2 | 210 | 743 | 30 | 97 |
| Example 3 | 197 | 917 | 37 | 138 |
| Example 4 | 240 | 983 | 40 | 157 |
| Example 5 | 265 | 1130 | 45 | 192 |
| Example 6 | 356 | 1053 | 41 | 173 |
| Example 7 | 310 | 1074 | 43 | 182 |
| Example 8 | 384 | 1018 | 41 | 184 |

In Examples 2-8, the treatment time, air-side temperature (upper-surface heating temperature), and steel belt-side temperature (lower-surface heating temperature) of the Zone A (first heating and drying treatment), the Zone B (first stack heating treatment), the Zone C (second heating and drying treatment), the Zone D (third heating and drying treatment), the Zone E (fourth heating and drying treatment), the Zone F (fifth heating and drying treatment), and the Zone G (sixth heating and drying treatment) are shown in Table 5.

TABLE 5

| | | Zone | Zone | Zone | Zone | Zone | Zone | Zone |
|---|---|---|---|---|---|---|---|---|
| Name | | A | B | C | D | E | F | G |
| Example | Time (min) | 4.5 | 6 | 6 | 3 | 6 | 6 | 4.5 |
| 2 | Air-Side | 80 | 85 | 100 | 105 | 100 | 85 | 80 |
| | Temperature (° C.) | | | | | | | |
| | Steel belt-side | 100 | 125 | 140 | 160 | 140 | 125 | 100 |
| | temperature (° C.) | | | | | | | |
| Example | Time (min) | 4.5 | 6 | 6 | 3 | 6 | 6 | 4.5 |
| 3 | Air-Side | 85 | 85 | 100 | 105 | 100 | 85 | 85 |
| | Temperature (° C.) | | | | | | | |
| | Steel belt-side | 105 | 130 | 140 | 165 | 140 | 130 | 105 |
| | temperature (° C.) | | | | | | | |
| Example | Time (min) | 4.5 | 6 | 6 | 3 | 6 | 6 | 4.5 |
| 4 | Air-Side | 85 | 90 | 105 | 110 | 105 | 90 | 85 |
| | Temperature (° C.) | | | | | | | |
| | Steel belt-side | 105 | 135 | 140 | 165 | 140 | 135 | 105 |
| | temperature (° C.) | | | | | | | |
| Example | Time (min) | 4.5 | 6 | 6 | 3 | 6 | 6 | 4.5 |
| 5 | Air-Side | 85 | 90 | 105 | 120 | 105 | 90 | 85 |
| | Temperature (° C.) | | | | | | | |
| | Steel belt-side | 105 | 135 | 145 | 170 | 145 | 135 | 105 |
| | temperature (° C.) | | | | | | | |
| Example | Time (min) | 5 | 6.6 | 6.6 | 3.3 | 6.6 | 6.6 | 5 |
| 6 | Air-Side | 85 | 90 | 105 | 120 | 105 | 90 | 85 |
| | Temperature (° C.) | | | | | | | |
| | Steel belt-side | 105 | 135 | 145 | 170 | 145 | 135 | 105 |
| | temperature (° C.) | | | | | | | |
| Example | Time (min) | 5.5 | 7.3 | 7.3 | 3.6 | 7.3 | 7.3 | 5.5 |
| 7 | Air-Side | 85 | 90 | 105 | 120 | 105 | 90 | 85 |
| | Temperature (° C.) | | | | | | | |
| | Steel belt-side | 105 | 135 | 145 | 170 | 145 | 135 | 105 |
| | temperature (° C.) | | | | | | | |
| Example | Time (min) | 6 | 8 | 8 | 3.9 | 8 | 8 | 6 |
| 8 | Air-Side | 85 | 90 | 105 | 120 | 105 | 90 | 85 |
| | Temperature (° C.) | | | | | | | |
| | Steel belt-side | 105 | 135 | 145 | 170 | 145 | 135 | 105 |
| | temperature (° C.) | | | | | | | |

### Examples 9-10

Examples 9-10 use another device to prepare a polyimide film with a three-layer structure. This device is basically the same as the device in FIG. 1, except that it also includes a third extrusion die head, which is located at the front end of Zone C and the rear end of Zone B (the travelling direction of the steel belt is the front end). Examples 9-10 are basically the same as Example 1, except that:
the chemical imidization reagent and molecular weight reinforcing agent from \textcircled{1} and \textcircled{2}, as well as the second resin solution, are quantitatively pumped into a mixer and fully mixed to obtain the second resin mixed solution; the second resin mixed solution is pumped into the second extrusion die head and the third extrusion die head respectively; the second resin mixed solution extruded by the second extrusion die head is cast onto the upper surface of the initial film layer A and heated in the Zone B; when the formed composite system travels to the junction of the Zone B and the Zone C, the second resin mixed solution extruded by the third extrusion die head is cast onto the upper surface of the composite system and heated in the Zone C to obtain an initial composite gel film with a three-layer structure (i.e., two stack heating treatments are performed on the initial film layer A using the second resin mixed solution);
the initial composite gel film travels with the steel belt, undergoing the second drying treatment in the Zone D, the third drying treatment in the Zone E, the fourth drying treatment in the Zone F, and the fifth drying treatment in the Zone G, to obtain the intermediate composite gel film. The intermediate composite gel film is longitudinally stretched at room temperature, then transversely stretched at 150° C.-600° C. and cooled to obtain a three-layer polyimide film.

The specific feeding flow rate data of each extrusion die head are shown in Table 6.

TABLE 6

| | | | Example | Example |
|---|---|---|---|---|
| Name | | | 9 | 10 |
| Feeding | First | First resin solution | 384 | 414 |
| flow | extrusion | | | |
| rate | die head | | | |
| (g/min) | Second | Second resin solution | 375 | 424 |
| | extrusion | Chemical imidization | 64 | 72 |
| | die head | reagent | | |
| | | Molecular weight | 15 | 16 |
| | | reinforcing agent | | |
| | Third | Second resin solution | 765 | 780 |
| | extrusion | Chemical imidization | 153 | 156 |
| | die head | reagent | | |
| | | Molecular weight | 30 | 31 |
| | | reinforcing agent | | |

In Examples 9-10, the treatment time, air-side temperature (upper-surface heating temperature), and steel belt-side temperature (lower-surface heating temperature) of the Zone A (first heating and drying treatment), the Zone B (first stack heating treatment), the Zone C (second stack heating treatment), the Zone D (second heating and drying treatment), the Zone E (third heating and drying treatment), the Zone F (fourth heating and drying treatment), and the Zone G (fifth heating and drying treatment) are shown in Table 7.

TABLE 7

| | | Zone | Zone | Zone | Zone | Zone | Zone | Zone |
|---|---|---|---|---|---|---|---|---|
| Name | | A | B | C | D | E | F | G |
| Example | Time (min) | 6.5 | 8.7 | 8.7 | 4.3 | 8.7 | 8.7 | 6.5 |
| 9 | Air-Side | 95 | 100 | 120 | 135 | 120 | 100 | 95 |
| | Temperature (° C.) | | | | | | | |
| | Steel belt-side | 115 | 130 | 150 | 170 | 150 | 130 | 115 |
| | temperature (° C.) | | | | | | | |
| Example | Time (min) | 7 | 9.4 | 9.4 | 4.6 | 9.4 | 9.4 | 7 |
| 10 | Air-Side | 95 | 100 | 120 | 135 | 120 | 100 | 95 |
| | Temperature (° C.) | | | | | | | |
| | Steel belt-side | 115 | 130 | 150 | 170 | 150 | 130 | 115 |
| | temperature (° C.) | | | | | | | |

### Example 11

This example is basically the same as Example 2, except that the preparation process of the first resin solution is as follows:
under the protection of nitrogen, 4000 g DMAc and 2000 g butanone are added into a 15 L reaction kettle and then stirred; 1006 g GAPDS and 495 g DAT are weighted and added into the reaction kettle, and stirred at room temperature for 30 min; 4 g calcium pyrophosphate is weighed and added into the reaction kettle and stirred for 20 min; 1306 g BTDA and 1192 g a-BPDA are weighed and added slowly into the reaction kettle sequentially and stirred for 300 min to obtain the first polyamic acid resin solution with a solid content of 40% and a viscosity of 1903P; the obtained first polyamic acid resin solution is frozen and stored at −10° C. for later use.

### Example 12

This example is basically the same as Example 2, except that the preparation process of the second resin solution is as follows:
under the protection of nitrogen, 10080 g DMF is added into a 20 L reaction kettle and then stirred; 1638 g ODA and 380 g PDA are weighed and added into the reaction kettle, and stirred at room temperature for 30 min; 4.5 g calcium pyrophosphate is weighed and added into the reaction kettle and stirred for 20 min; 2296 g PMDA is weighed and added slowly into the reaction kettle sequentially, and stirred for 300 min to obtain the second polyamic acid resin solution with a solid content of 30% and a viscosity of 2536P; the obtained second polyamic acid resin solution is frozen and stored at −10° C. for later use.

### Example 13

This example is basically the same as Example 2, except that the preparation process of the first resin solution is as follows:
under the protection of nitrogen, 3669 g DMAc and 1223 g butanone are added into a 15 L reaction kettle and then stirred; 1006 g GAPDS and 495 g DAT are weighed and added into the reaction kettle, and stirred at room temperature for 30 min; 4 g calcium pyrophosphate is weighed and added into the reaction kettle and stirred for 20 min; 1306 g BTDA and 1192 g a-BPDA are weighed and added slowly into the reaction kettle sequentially and stirred for 300 min to obtain the first polyamic acid resin solution with a solid content of 45% and a viscosity of 1822P; the obtained first polyamic acid resin solution is frozen and stored at −10° C. for later use.

### Example 14

This example is basically the same as Example 2, except that the preparation process of the second resin solution is as follows:
under the protection of nitrogen, 8070 g DMF is added into a 20 L reaction kettle and then stirred; 1638 g ODA and 380 g PDA are weighed and added into the reaction kettle, and stirred at room temperature for 30 min; 4.5 g calcium pyrophosphate is weighed and added into the reaction kettle and stirred for 20 min; 2246 g PMDA is weighed and added slowly into the reaction kettle sequentially and stirred for 300 min to obtain the second polyamic acid resin solution with a solid content of 34.5% and a viscosity of 2337P; the obtained second polyamic acid resin solution is frozen and stored at −10° C. for later use.

### Example 15

This example is basically the same as Example 2, except that the configuration of the chemical imidization reagent is as follows:
under the protection of nitrogen, 800 g DMF, 2198 g acetic anhydride, 1390 g isoquinoline, and 200 g triphenyl phosphate are added sequentially into a 5 L reaction kettle, and stirred for 180 min for later use.

### Example 16

This example is basically the same as Example 2, except that the configuration of the molecular weight reinforcing agent is as follows:
under the protection of nitrogen, 1200 g DMF and 600 g 1,2,3,4-cyclobutanetetracarboxylic acid are added sequentially into a 2 L reaction kettle, and stirred at room temperature for 120 min for later use.

### Comparative Example 1

This comparative example adopts the second resin mixed solution (including the second resin solution, chemical imidization reagent, and molecular weight reinforcing agent solution) used in Example 2 to prepare an ultra-thick polyimide film with a single-layer structure, that is, the second resin solution, chemical imidization reagent, and molecular weight reinforcing agent solution are quantitatively pumped into the mixer, mixed, and pumped into the second extrusion die head, with the remaining procedures being the same as Example 2.

### Comparative Example 2

The first resin solution in Example 2 is used to prepare an ultra-thick polyimide film with a single-layer structure, that is, the first polyamic acid resin solution is pumped into the first extrusion die head, with the remaining procedures being the same as Example 2.

### Comparative Example 3

The second resin solution, chemical imidization reagent, molecular weight reinforcing agent, and first resin solution in Example 2 are used to prepare a film layer A and a film layer B respectively, with the remaining procedures being the same as Example 2.

### Comparative Example 4

1) Preparation of a first polyamic acid resin solution
under the protection of nitrogen, 4767 g DMF and 1559 g THF are added into a 15 L reaction kettle and then start stirred; 622 g BAPP is weighed and added into the reaction kettle, and stirred at room temperature for 30 min; 1.5 g calcium pyrophosphate is weighed and added into the reaction kettle and stirred for 20 min; 469 g ODPA and 303 g 3,4-ODA are weighed and added slowly into the reaction kettle sequentially and stirred for 300 min to obtain the first polyamic acid resin solution with a solid content of 18% and a viscosity of 2239P; the obtained first polyamic acid resin solution is frozen and stored at −10° C. for later use.

2) Preparation of a second polyamic acid resin solution
under the protection of nitrogen, 10972 g DMF is added into a 20 L reaction kettle and then stirred; 585 g ODA and 316 g PDA are weighed and added into the reaction kettle, and stirred at room temperature for 30 min; 1.5 g calcium pyrophosphate is weighed and added into the reaction kettle and stirred for 20 min; 637 g PMDA and 869 g s-BPDA are weighed and added slowly into the reaction kettle sequentially and stirred for 300 min to obtain the second polyamic acid resin solution with a solid content of 18% and a viscosity of 1706P; the obtained second polyamic acid resin solution is frozen and stored at −10° C. for later use.

The remaining procedures are the same as Example 2. The prepared two-layer-structure composite gel film has a solvent content of 561% and a tensile strength of 21 MPa; during high-temperature treatment, the gel film detaches from the fixture, making it impossible to stably produce a 300 μm-thick polyimide film.

### Comparative Example 5

This comparative example is basically the same as Example 2, except that the treatment time, air-side temperature (upper-surface heating temperature), and steel belt-side temperature (lower-surface heating temperature) of the Zone A (first heating and drying treatment), the Zone B (first stack heating treatment), the Zone C (second heating and drying treatment), the Zone D (third heating and drying treatment), the Zone E (fourth heating and drying treatment), the Zone F (fifth heating and drying treatment), and the Zone G (sixth heating and drying treatment) are shown in Table 8.

TABLE 8

| | Zone | Zone | Zone | Zone | Zone | Zone | Zone |
|---|---|---|---|---|---|---|---|
| Name | A | B | C | D | E | F | G |
| Time (min) | 4.5 | 6 | 6 | 3 | 6 | 6 | 4.5 |
| Air-Side | 100 | 120 | 135 | 160 | 135 | 120 | 100 |
| Temperature (° C.) | | | | | | | |
| Steel Belt-Side | 100 | 120 | 135 | 160 | 135 | 120 | 100 |
| Temperature (° C.) | | | | | | | |

### Comparative Example 6

This comparative example is basically the same as Example 2, except that the treatment time, air-side temperature (upper-surface heating temperature), and steel belt-side temperature (lower-surface heating temperature) of the Zone A (first heating and drying treatment), the Zone B (first stack heating treatment), the Zone C (second heating and drying treatment), the Zone D (third heating and drying treatment), the Zone E (fourth heating and drying treatment), the Zone F (fifth heating and drying treatment), and the Zone G (sixth heating and drying treatment) are shown in Table 9.

TABLE 9

| | Zone | Zone | Zone | Zone | Zone | Zone | Zone |
|---|---|---|---|---|---|---|---|
| Name | A | B | C | D | E | F | G |
| Time (min) | 4.5 | 6 | 6 | 3 | 6 | 6 | 4.5 |
| Air-Side | 50 | 55 | 60 | 65 | 60 | 55 | 50 |
| Temperature (° C.) | | | | | | | |
| Steel Belt-Side | 100 | 125 | 145 | 165 | 145 | 125 | 100 |
| Temperature (° C.) | | | | | | | |

### Test Example

The solvent content and tensile strength of the gel films, as well as the thickness of the produced ultra-thick polyimide films in the foregoing examples and comparative examples, are counted; and the data are shown in Table 10.

TABLE 10

| | Solvent | Tensile | Structure and thickness of ultra-thick | | | |
|---|---|---|---|---|---|---|
| | content of | strength of | polyimide composite film (μm) | | | |
| | intermediate | intermediate | Thickness | Thickness | Thickness | Total |
| | composite | composite | of layer | of layer | of layer | thickness |
| Name | gel film (%) | gel film (MPa) | 1 (μm) | 2 (μm) | 3 (μm) | (μm) |
| Example 1 | 93 | 61 | 53 | 199 | — | 252 |
| Example 2 | 104 | 67 | 84 | 223 | — | 307 |
| Example 3 | 136 | 79 | 79 | 275 | — | 354 |
| Example 4 | 147 | 92 | 96 | 295 | — | 391 |
| Example 5 | 184 | 102 | 106 | 339 | — | 445 |
| Example 6 | 203 | 111 | 158 | 351 | — | 509 |
| Example 7 | 231 | 122 | 151 | 393 | — | 544 |
| Example 8 | 265 | 143 | 205 | 407 | — | 612 |
| Example 9 | 288 | 156 | 205 | 150 | 306 | 661 |
| Example 10 | 307 | 171 | 221 | 170 | 312 | 703 |
| Example 11 | 99 | 71 | 79 | 232 | — | 311 |
| Example 12 | 91 | 82 | 80 | 223 | — | 303 |
| Example 13 | 87 | 66 | 82 | 226 | — | 308 |
| Example 14 | 83 | 57 | 78 | 215 | — | 293 |
| Example 15 | 95 | 63 | 81 | 224 | — | 305 |
| Example 16 | 90 | 59 | 83 | 206 | — | 299 |
| Comparative | x | x | x | x | — | x |
| Example 1 | | | | | | |
| Comparative | x | x | x | x | — | x |
| Example 2 | | | | | | |
| Comparative | x | x | x | x | — | x |
| Example 3 | | | | | | |
| Comparative | 561 | 21 | x | x | — | x |
| Example 4 | | | | | | |
| Comparative | 372 | 36 | x | x | — | x |
| Example 5 | | | | | | |
| Comparative | 167 | 72 | 82 | 213 | — | 295* |
| Example 6 | | | | | | |

Note:
x-cannot prepare the gel film for testing;
*-there are streak defects on the film surface.

Where:
1) During the preparation of Comparative Example 1, the gel film shrinks and tears during drying, making production impossible. This indicates that a single-layer polyimide film cannot be prepared using only the second resin mixed solution;
2) During the preparation of Comparative Example 2, the gel film adheres to the steel belt after drying and is difficult to be peeled off, and the gel film tears under tension, making production impossible. This indicates that a single-layer polyimide film also cannot be prepared using only the first resin solution;
3) During the preparation of Comparative Example 3, the gel film shrinks and tears during drying, making production impossible. This indicates that the polyimide film cannot be prepared when the corresponding relationship between the first and second resin solutions and film layers A and B is reversed;
4) The two-layer intermediate composite gel film prepared in Comparative Example 4 has a solvent content of 561% and a tensile strength of 21 MPa; during high-temperature treatment, the gel film detaches from the fixture, making it impossible to stably produce a 300 μm-thick polyimide film. This indicates that it is difficult to prepare polyimide film products when the solvent content of the intermediate composite gel film is too high;
5) The intermediate composite gel film prepared in Comparative Example 5 has a solvent content of 372% and a tensile strength of 36 MPa; during high-temperature treatment, the gel film detaches from the fixture, making it impossible to stably produce a 300 μm-thick polyimide film. This indicates that it is difficult to prepare polyimide film products when the solvent content of the intermediate composite gel film is too high;
6) During the drying of the gel film in Comparative Example 6, a large amount of solvent drips back to the surface to form streak defects; the prepared gel film has a solvent content of 167% and a tensile strength of 72 MPa; after biaxial stretching and high-temperature treatment, a 295 μm-thick polyimide film can be produced. This indicates that when the air-side temperature is too low, there are streak defects formed by a large amount of solvent dripping back to the surface;
7) In addition, the air-side heating temperature is low and there is a large temperature difference between the air-side heating temperature and the steel belt-side heating temperature, which will not only cause the solvent to drip back to the film surface to form defects, but also cause insufficient drying of the gel film, resulting in a high solvent content of product, and lower comprehensive performance of the finally prepared composite film.

The structure and performance statistics of the ultra-thick polyimide films in the above examples are shown in Table 11. The measurement methods are as follows.

Thickness measurement method: using a CHY-CA mechanical contact thickness gauge from China Saicheng Instruments for measurement.

CTE measurement method: using a TMA450 static thermomechanical analyzer from TA Instruments, USA for measurement, with a heating rate of 3° C./min.

Breakdown voltage measurement method: using an SDJ-150 KV type film voltage breakdown tester from China Guanheng Jingdian Instrument Equipment for measurement, with a voltage rise rate of 500V/s.

H₂ permeability measurement method: using an SMT-275 membrane separation test analyzer from China Sike Testing Technology for measurement, with a hydrogen inlet rate of 50 ml/min.

Surface roughness (Rz) measurement method: using a Marsurf VD140 280 profile roughness measuring instrument from Mahr, Germany for measurement.

Glass transition temperature (Tg) measurement method: using a DMA303 from Netzsch, Germany for measurement, with a heating rate of 3° C./min.

Micropore number measurement method: the cross-section of the polyimide film sample is detected using a GeminiSEM 360 scanning electron microscope from Zeiss, Germany; and the number of micropores with a size greater than 0.1 mm is counted.

Density measurement method: using a DH-300 film rapid densitometer from China Hongtuo Instruments for detection.

TABLE 11
Structural performance statistics of polyimide films

| | | | | | | | Film | | |
|---|---|---|---|---|---|---|---|---|---|
| | | | | | | | Layer B | | |
| | Composite Film | | | | | | | Number | |
| | | | | H₂ perme- | Film | | | of micro- | |
| | Thick- | | | ability | Layer A | | | pores ≥0.1 | |
| | ness | CTE | BV | (mol · m/m² · | Rz | Tg | Rz | mm (unit/ | ρ |
| Name | (μm) | (ppm/° C.) | (KV) | s · Pa) | (μm) | (° C.) | (μm) | 5 m²) | (g/cm³) |
| Example 1 | 252 | 15.3 | 35.1 | 5.36 × 10⁻¹⁵ | 0.91 | 265 | 1.36 | 0 | 1.48 |
| Example 2 | 307 | 16.1 | 42.1 | 7.95 × 10⁻¹⁵ | 0.88 | 265 | 1.41 | 0 | 1.48 |
| Example 3 | 354 | 16.5 | 51.3 | 9.24 × 10⁻¹⁵ | 0.83 | 265 | 1.47 | 1 | 1.48 |
| Example 4 | 391 | 17.2 | 54.7 | 1.33 × 10⁻¹⁶ | 0.92 | 265 | 1.46 | 2 | 1.48 |
| Example 5 | 445 | 18.4 | 62.3 | 4.91 × 10⁻¹⁶ | 0.86 | 265 | 1.52 | 2 | 1.47 |
| Example 6 | 509 | 19.6 | 68.7 | 8.82 × 10⁻¹⁶ | 0.81 | 265 | 1.58 | 3 | 1.47 |
| Example 7 | 544 | 20.5 | 71.9 | 2.55 × 10⁻¹⁷ | 0.90 | 265 | 1.67 | 3 | 1.47 |
| Example 8 | 612 | 23.2 | 79.6 | 7.33 × 10⁻¹⁷ | 0.95 | 265 | 1.73 | 4 | 1.46 |
| Example 9 | 661 | 24.1 | 85.9 | 1.68 × 10⁻¹⁸ | 0.97 | 265 | 1.85 | 5 | 1.45 |
| Example 10 | 703 | 26.6 | 91.4 | 8.11 × 10⁻¹⁸ | 0.91 | 265 | 1.99 | 5 | 1.45 |
| Example 11 | 311 | 18.8 | 42.9 | 7.05 × 10⁻¹⁵ | 0.85 | 203 | 1.40 | 1 | 1.48 |
| Example 12 | 303 | 16.0 | 41.4 | 6.31 × 10⁻¹⁵ | 0.96 | 265 | 1.39 | 0 | 1.45 |
| Example 13 | 308 | 18.3 | 42.3 | 7.39 × 10⁻¹⁵ | 0.80 | 207 | 1.40 | 2 | 1.48 |
| Example 14 | 293 | 15.7 | 40.1 | 5.93 × 10⁻¹⁵ | 0.97 | 265 | 1.36 | 2 | 1.45 |
| Example 15 | 305 | 16.4 | 41.7 | 6.77 × 10⁻¹⁵ | 0.83 | 265 | 1.39 | 1 | 1.48 |
| Example 16 | 299 | 15.8 | 41.0 | 5.80 × 10⁻¹⁵ | 0.82 | 265 | 1.37 | 0 | 1.48 |
| Comparative | 295 | 16.7 | 40.2 | 1.23 × 10⁻¹³ | 0.85 | 265 | 1.39 | 11 | 1.43 |
| example 6 | | | | | | | | | |

CTE: linear thermal expansion coefficient; BV: breakdown voltage; Rz: surface roughness; Tg: glass transition temperature; ρ: density.

It can be seen from Table 11 that the polyimide films prepared in each example of the present application all have the characteristics of large thickness, low thermal expansion, high pressure resistance, and low gas permeability.

In the description of the embodiments of the present application, it should be noted that unless otherwise clearly specified and limited, the terms “installation”, “connection”, and “linkage” should be understood in a broad sense. For example, it can be a fixed connection, an indirect connection through an intermediate medium, internal communication between two components, or an interaction relationship between two components. For those of ordinary skill in the art, the specific meanings of the above terms in the present application can be understood according to specific situations.

In the specification, claims, and the above drawings of the present application, terms such as “first”, “second”, “third”, “fourth” (if present) are used to distinguish similar objects, rather than to describe a specific order or sequence. It should be understood that the data used in this way can be interchanged under appropriate circumstances, so that the embodiments of the present application described herein can be implemented in an order other than those illustrated or described herein, for example. In addition, the terms “include” and “have” and any variations thereof are intended to cover non-exclusive inclusion. For example, a process, method, system, product, or device that includes a series of steps or units is not necessarily limited to the clearly listed steps or units, but may include other steps or units that are not clearly listed or that are inherent to these processes, methods, products, or devices.

Finally, it should be noted that the above embodiments are only used to illustrate the technical solutions of the present application, not to limit them; although the present application has been described in detail with reference to the foregoing embodiments and comparative examples, those of ordinary skill in the art should understand that they can still modify the technical solutions recorded in the foregoing embodiments, or equivalently replace some or all of the technical features; and these modifications or replacements do not make the essence of the corresponding technical solutions deviate from the technical solutions of the embodiments of the present application.

What is claimed is:

1. A polyimide film, wherein the polyimide film has a thickness of greater than or equal to 250 μm and comprises a film layer A and at least one film layer B that are in contact with each other;
the film layer A has a surface roughness Rz of less than or equal to 1.0 μm;
a micropore with a size greater than 0.1 mm in the film layer B is less than or equal to 1 per square meter in number, and the film layer B has a density of greater than or equal to 1.45 g/cm³, and a surface roughness Rz of greater than or equal to 1.2 μm.

2. The polyimide film according to claim 1, wherein the polyimide film has a linear thermal expansion coefficient of 12 ppm/° C. to 35 ppm/° C., a breakdown voltage of greater than or equal to 30 kV, and a permeability to H₂ of less than or equal to 1.0×10⁻¹⁵ mol·m/m²·s·Pa; and polyimide in the film layer A has a glass transition temperature of 180° C.-300° C.

3. The polyimide film according to claim 1, wherein a thickness of the film layer A accounts for 20%-50% of a total thickness of the polyimide film.

4. A preparation method of the polyimide film according to claim 1, comprising the following steps:
1) mixing a first aromatic dianhydride, a first aromatic diamine, a low-boiling solvent, a high-boiling solvent, and a filler, and allowing the first aromatic dianhydride and the first aromatic diamine to undergo a polycondensation reaction to obtain a first resin solution;
2) mixing a second aromatic dianhydride, a second aromatic diamine, a high-boiling solvent, and a filler, and allowing the second aromatic dianhydride and the second aromatic diamine to undergo a polycondensation reaction to obtain a second resin solution;
3) performing a first heating and drying treatment on a solution film formed by casting the first resin solution to obtain an initial film layer A;
4) mixing the second resin solution with a chemical imidization reagent and a molecular weight reinforcing agent to obtain a second resin mixed solution; performing at least one stack heating treatment on the initial film layer A using the second resin mixed solution to obtain an initial composite gel film;
5) sequentially performing at least one heating and drying treatment on the initial composite gel film to obtain an intermediate composite gel film;
6) performing a high-temperature heating and biaxial stretching treatment on the intermediate composite gel film to obtain the polyimide film; wherein
the first heating and drying treatment has a treatment temperature of 50° C. to 120° C., and a treatment time of 2 min to 10 min;
the stack heating treatment comprises attaching the second resin mixed solution to one-side surface of the initial film layer A, and performing a heating treatment at a temperature of 60° C. to 150° C. for a time of 5 min to 15 min;
the heating and drying treatment for the initial composite gel film has a treatment temperature of 50° C.-180° C., and a treatment time of 18 min-60 min;
the first aromatic dianhydride is selected from at least one of pyromellitic dianhydride, 3,3′,4,4′-biphenyltetracarboxylic dianhydride, 2,3,3′,4-biphenyltetracarboxylic dianhydride, 4,4′-oxydiphthalic dianhydride, 3,4,3′,4′-triphenyl diether dianhydride, 2,2-bis[4-(3,4-dicarboxyphenoxy)phenyl]propane dianhydride, 2,2-diphenylpropane-3,4,3′,4′-tetracarboxylic dianhydride, 3,3′,4,4′-benzophenonetetracarboxylic dianhydride, 3,3′,4,4′-diphenyl sulfone tetracarboxylic dianhydride, and p-phenylene-bis-trimellitate dianhydride;
the first aromatic diamine is selected from at least one of 4,4′-diaminodiphenyl ether, 2,2-bis[4-(4-aminophenoxy)phenyl]propane, 4,4′-diaminodiphenylmethane, 2,2-bis(4-aminophenyl)propane, 1,3-bis(3-aminophenoxy)benzene, 1,4-bis(4-aminophenoxy)benzene, 2,4-diaminotoluene, and 1,3-bis(aminopropyl)tetramethyldisiloxane;
the second aromatic dianhydride is selected from at least one of pyromellitic dianhydride and 3,3′,4,4′-biphenyltetracarboxylic dianhydride;
the second aromatic diamine is selected from at least one of 4,4′-diaminodiphenyl ether and 1,4-phenylenediamine;
a solid content of the first resin solution is 10%-50%;
a solid content of the second resin solution is 10%-35%;
the low-boiling solvent is selected from at least one of acetone, butanone, toluene, ethyl acetate, tetrahydrofuran, and chloroform;
the high-boiling solvent is selected from at least one of N,N-dimethylformamide, N,N-dimethylacetamide, and N-methylpyrrolidone;
the filler is selected from at least one of calcium carbonate, calcium phosphate, calcium pyrophosphate, calcium hydrogen phosphate, silicon carbide, carbon nanotubes, graphene, carbon black, silicon dioxide, and titanium dioxide;
the chemical imidization reagent comprises a dehydrating agent, a catalyst, an imidization solvent, and an additive;
the dehydrating agent is selected from at least one of acetic anhydride, trifluoroacetic anhydride, benzoic anhydride, acetyl chloride, and thionyl chloride;
the catalyst is selected from at least one of quinoline, isoquinoline, pyridine, 3-methylpyridine, triethylamine, and N-methylimidazole;
the imidization solvent is selected from at least one of N,N-dimethylformamide, N,N-dimethylacetamide, and N-methylpyrrolidone;
the additive is selected from at least one of tricresyl phosphate, triphenyl phosphate, cresyldiphenyl phosphate, and trioctyl trimellitate;
the molecular weight reinforcing agent comprises at least one of 1,2,4,5-benzenetetracarboxylic acid, 3,3′,4,4′-biphenyltetracarboxylic acid, tetrahydrofuran-2,3,4,5-tetracarboxylic acid, cyclohexane-1,2,4,5-tetracarboxylic acid, 1,2,3,4-cyclobutanetetracarboxylic acid, terephthalic acid, isophthalic acid, and terephthaloyl chloride;
a heating temperature of the high-temperature heating and biaxial stretching treatment in step 6) is 150° C.-600° C.

5. The preparation method of the polyimide film according to claim 4, wherein the polyimide film has a linear thermal expansion coefficient of 12 ppm/° C. to 35 ppm/° C., a breakdown voltage of greater than or equal to 30 kV, and a permeability to H₂ of less than or equal to 1.0×10⁻¹⁵ mol·m/m²·s·Pa; and polyimide in the film layer A has a glass transition temperature of 180° C.-300° C.

6. The preparation method of the polyimide film according to claim 4, wherein a thickness of the film layer A accounts for 20%-50% of a total thickness of the polyimide film.

7. The preparation method of the polyimide film according to claim 4, wherein in step 1), a molar ratio of the first aromatic dianhydride to the first aromatic diamine is 0.99:1 to 1.05:1; and/or,
a molar ratio of the second aromatic dianhydride to the second aromatic diamine is 0.8:1 to 0.995:1.

8. The preparation method of the polyimide film according to claim 5, wherein in step 1), a molar ratio of the first aromatic dianhydride to the first aromatic diamine is 0.99:1 to 1.05:1; and/or,
a molar ratio of the second aromatic dianhydride to the second aromatic diamine is 0.8:1 to 0.995:1.

9. The preparation method of the polyimide film according to claim 6, wherein in step 1), a molar ratio of the first aromatic dianhydride to the first aromatic diamine is 0.99:1 to 1.05:1; and/or,
a molar ratio of the second aromatic dianhydride to the second aromatic diamine is 0.8:1 to 0.995:1.

10. The preparation method of the polyimide film according to claim 4, wherein a solid content of the first resin solution is 30%-40%; and/or,
a solid content of the second resin solution is 25%-35%.

11. The preparation method of the polyimide film according to claim 5, wherein a solid content of the first resin solution is 30%-40%; and/or,
a solid content of the second resin solution is 25%-35%.

12. The preparation method of the polyimide film according to claim 6, wherein a solid content of the first resin solution is 30%-40%; and/or,
a solid content of the second resin solution is 25%-35%.

13. The preparation method of the polyimide film according to claim 4, wherein a mass of the chemical imidization reagent is 1%-30% of a mass of the second resin solution; and/or,
in the chemical imidization reagent, a molar ratio of the dehydrating agent to the catalyst is 1:2 to 5:1, a mass fraction of the imidization solvent is 10%-40%, and a mass fraction of the additive is 1%-10%; and/or,
a mass of the filler is 0.05%-5% of a total mass of the aromatic diamine and the aromatic dianhydride.

14. The preparation method of the polyimide film according to claim 4, wherein an amount of substance of the molecular weight reinforcing agent is equal to a difference in an amount of substance between the second aromatic diamine and the second aromatic dianhydride.

15. The preparation method of the polyimide film according to claim 4, wherein in step 5), the heating and drying treatment comprises heating an upper surface and a lower surface of the initial composite gel film respectively, wherein a heating temperature of the upper surface is 50° C.-150° C., and a heating temperature of the lower surface is 80° C.-180° C.

16. The preparation method of the polyimide film according to claim 4, wherein in step 5), the heating and drying treatment performed on the initial composite gel film comprises a second heating and drying treatment, a third heating and drying treatment, a fourth heating and drying treatment, a fifth heating and drying treatment, and a sixth heating and drying treatment that are performed in sequence;
the second heating and drying treatment has an upper-surface heating temperature of 80° C.-120° C., a lower-surface heating temperature of 120° C.-150° C., and a treatment time of 5 min-15 min;
the third heating and drying treatment has an upper-surface heating temperature of 90° C.-135° C., a lower-surface heating temperature of 135° C.-180° C., and a treatment time of 1 min-8 min;
the fourth heating and drying treatment has an upper-surface heating temperature of 80° C.-120° C., a lower-surface heating temperature of 120° C.-150° C., and a treatment time of 5 min-15 min;
the fifth heating and drying treatment has an upper-surface heating temperature of 60° C.-120° C., a lower-surface heating temperature of 120° C.-150° C., and a treatment time of 5 min-15 min;
the sixth heating and drying treatment has an upper-surface heating temperature of 50° C.-100° C., a lower-surface heating temperature of 100° C.-120° C., and a treatment time of 2 min-10 min.

17. The preparation method of the polyimide film according to claim 4, wherein in the stack heating treatment, the stack heating treatment has an upper-surface heating temperature of 60° C.-120° C., and a lower-surface heating temperature of 120° C.-180° C.

18. A circuit board, comprising the polyimide film according to claim 1.

19. A gas barrier composite film, comprising the polyimide film according to claim 1.

20. An insulating composite film, comprising the polyimide film according to claim 1.
